(19) United States
(12) Patent Application Publication
(10) Pub. No.: US 2012/0325287 A1
(43) Pub. Date: Dec. 27, 2012

(54) PHOTONIC ENERGY CONCENTRATOR WITH INTEGRAL SUPPORT RIBS

(76) Inventor: Stephan R. Clark, Albany, OR (US)

(21) Appl. No.: 13/169,445

(22) Filed: Jun. 27, 2011

(51) Int. Cl. H01L 31/052; G02B 5/10; B29D 11/00

(52) U.S. Cl. 136/246; 264/1.1; 359/853

(57) ABSTRACT

Apparatus and methods are provided for use with solar energy. A curved surface includes integral support ribs extending away from a backside thereof. A dichroic surface treatment is born on the curved surface to define a curved dichroic surface. A curved reflector is disposed apart from the backside of the curved dichroic surface. Photovoltaic cells can be disposed at respective photonic energy concentration regions defined by the curved dichroic surface and the curved reflector.

### STATEMENT OF GOVERNMENT INTEREST

The invention that is the subject of this patent application was made with Government support under Subcontract No. CW135971, under Prime Contract No. HR0011-07-9-0005, through the Defense Advanced Research Projects Agency (DARPA). The Government has certain rights in this invention.

### BACKGROUND

Solar energy devices and apparatus make use of incident sunlight for direct conversion to electrical energy, to heat water or other fluids, and so on. Improvements in solar energy capture and conversion efficiency, and decreased cost of manufacturing such devices and systems, are constantly sought after. The present teachings address the foregoing and other concerns.

### BRIEF DESCRIPTION OF THE DRAWINGS

The present embodiments will now be described, by way of example, with reference to the accompanying drawings, in which:

FIG. 1 is an isometric-like view of a light concentrator according to one example of the present teachings;

FIG. 2 is a side elevation view of a portion of a device according to another example;

FIG. 3 is a schematic view of an optical arrangement according to another example;

FIG. 4 is an isometric-like view of a light concentrating device according to an example;

FIG. 5 is an isometric-like view of a light concentrating device according to an example;

FIG. 6 is an isometric-like/block diagram hybrid view of a solar energy system according to another example;

FIG. 7 is an isometric-like view of a double-curvature light concentrator according to an example;

FIG. 8 is a flow diagram depicting a method according to an example.

### DETAILED DESCRIPTION

### Introduction

Apparatus and methods are provided for use with solar energy. A curved surface includes integral support ribs extending away from a backside such that a monolithic structure is defined. A dichroic surface treatment is born on the curved surface. A curved reflector is disposed apart from the backside of the curved dichroic surface. Photovoltaic cells or other target entities are disposed at respective photonic energy concentration regions defined by the curved dichroic surface and the curved reflector. First and second spectral bands of incident photonic energies are concentrated on the respective target entities during normal typical operation.

In one example, an apparatus includes a first surface and plural support ribs extending away from a backside of the first surface, such that a monolithic structure is defined. The apparatus also includes a dichroic surface treatment borne on the first surface. The dichroic surface treatment is configured to concentrate a first spectral band of incident photonic energies onto a first target region. Also included is a second surface spaced apart from the backside of the first surface. The apparatus further includes a reflective surface treatment borne on the second surface so as to concentrate a second spectral band of photonic energies onto a second target region.

In another example, a solar energy device includes a first photovoltaic cell and a second photovoltaic cell. Each photovoltaic cell is configured to convert photonic energy into electrical energy. The device also includes a transparent material formed to define a first parabolic surface and stiffening support ribs extending away there from. The first parabolic surface bears a dichroic surface treatment so as to concentrate a first spectral band of photonic energies onto the first photovoltaic cell. The device additionally includes a material formed to define a second parabolic surface spaced apart from a backside of the first parabolic surface. The second parabolic surface bears a reflective surface treatment so as to concentrate a second spectral band of photonic energies onto the second photovoltaic cell.

In yet another example, a method includes forming a transparent material to define a first surface having a parabolic curvature in at least one axis. The transparent material is also formed to define stiffening support ribs extending away from a backside of the first surface. The method also includes applying a dichroic surface treatment to the first surface so as to concentrate a first spectral portion of incident light energy onto a first target region. The method further includes forming a material to define a second surface having a parabolic curvature in at least one axis. The method also includes applying a reflective surface treatment to the second surface to concentrate a second spectral portion of the incident light energy onto a second target region distinct from the first target region.

### Illustrative Light Concentrator

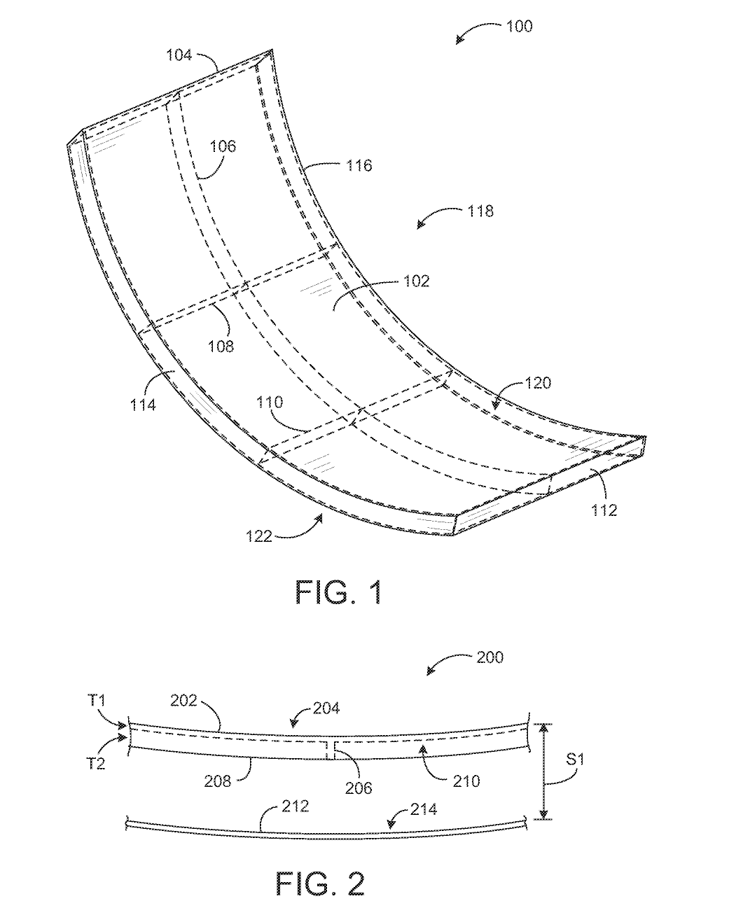

Reference is now directed to FIG. 1 which depicts an isometric-like view of a light concentrator (concentrator) 100. The concentrator 100 is illustrative and non-limiting with respect to the present teachings. Thus, other light concentrators, apparatus, devices or systems can be configured and/or operated in accordance with the present teachings.

The concentrator 100 includes a curved surface 102. The curved surface 102 is smooth and uniform in nature, defining a front side or “face” of the concentrator 100. In one example, the curved surface 102 is defined by a cross-sectional shape defined by a segment of a parabola. Other suitable geometries and form factors can also be used. The curved surface 102 can also be referred to as a parabolic surface 102 with respect to those corresponding examples.

The concentrator 100 also includes a plurality of support ribs 104-116, inclusive. Specifically: the support ribs 104 and 112 define respective end support ribs; the support rib 106 defines a longitudinal support rib; the support ribs 108 and 110 define respective transverse support ribs; and the support ribs 114 and 116 define respective side support ribs. The curved surface 102 and the support ribs 104-116 are formed as respective portions of the same continuous material such that a homogeneous (or monolithic) structure 118 is defined. The support ribs 106 and 108 and 110 are depicted completely in hidden (dashed) line format as they lie beneath and extend away from the backside of the curved surface 102 as seen by the viewer.

In one example, the monolithic structure 118 is formed by injection molding of plastic. In another example, glass is used to define the monolithic structure 118. Other suitable materials can also be used. The monolithic structure 118 is transparent in nature such that at least some spectra of photonic energies can pass there through. In turn, the support ribs 104-116 act as stiffening elements so as to maintain the desired curvature of the curved surface 102.

The concentrator 100 includes a dichroic surface treatment 120 borne by or formed upon the curved surface 102. The dichroic surface treatment 120 can be formed (or deposited) as one or more layers of one or more dichroic materials. Non-limiting examples of such dichroic materials include niobium pentoxide (Nb2O5), silicon dioxide (SiO2), titanium dioxide (TiO2), tantalum pentoxide (Ta2O5), zirconium pentoxide (Zr2O5), hafnium dioxide (HfO2), magnesium fluoride (MgF2) and aluminum oxide (Al2O3). Other suitable materials can also be used.

The dichroic surface treatment 120 is such that a first spectral band or portion of incident photonic energy is concentrated away from the curved surface 102 toward a strip-like region in space. A second spectral band of photonic energies pass through the dichroic surface treatment 120 and the curved surface 102. Further description of such photonic energy splitting and concentrating operations is provided below.

The light concentrator 100 further includes an anti-reflective coating or surface treatment 122 applied to or formed upon the backside of the curved surface 102. Non-limiting examples of such anti-reflective materials include silicon dioxide (SiO2) and titanium dioxide (TiO2) or niobium pentoxide (Nb2O5). Other suitable materials can also be used. The anti-reflective surface treatment 122 functions to reduce or prevent reflection (i.e., loss) of the second spectral band of incident photonic energies (or a portion thereof) that pass through the dichroic surface treatment 120 and the curved surface 102 material. In other examples, the anti-reflective surface treatment 122 is omitted.

In one example, the curved surface 102 has a uniform thickness of about 0.5 millimeters, while the respective support ribs 104-116 have a uniform thickness (extending away from the backside curved surface 102) in the range of about 1.0 to 2.5 millimeters. Other suitable thicknesses and dimensions can also be used. The light concentrator 100 typically used as a component or element within a solar energy device or system as described in further detail hereinafter.

It is noted that the curved surface 102 has a relatively thin thickness. This aspect of the present teachings results in light concentrators having relatively short injection molding-cycle times, minimal finished weight, and minimal material consumption and cost.

### Illustrative Device Details

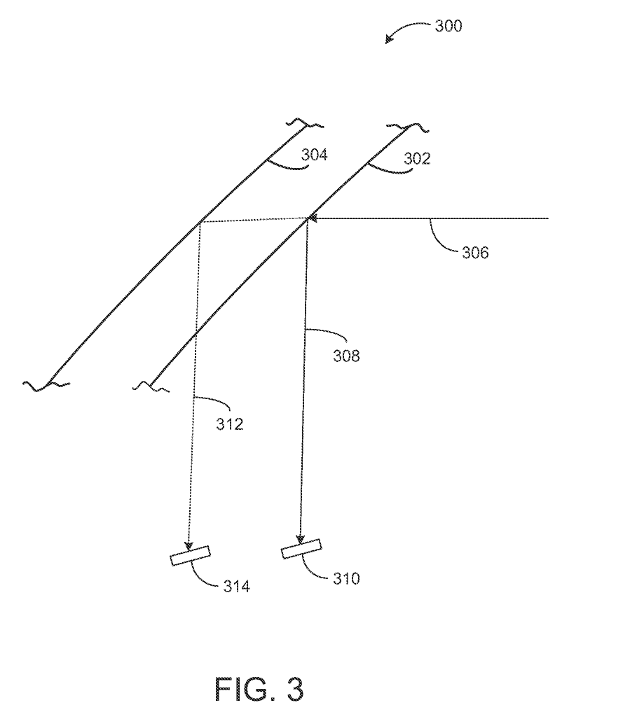

Attention is now turned to FIG. 2, which depicts a side elevation view of a portion of a device 200 in accordance with another example of the present teachings. The device 200 is illustrative and non-limiting with respect to the present teachings. Other devices, apparatus and systems can also be used. Only selected details of the device 200 are depicted in the interest of clarity of the present teachings.

The device 200 includes a curved surface 202. The curved surface 202 is defined by a parabolic, parabolic segment, or other suitable curvature. The curved surface 202 is formed from plastic, glass or another suitable transparent material. The curved surface is defined by a thickness “T1”. In one example, the thickness T1 is about 0.5 millimeters. Other suitable thicknesses can also be used. The curved surface 202 also bears a dichroic surface treatment 204 thereon. Such dichroic surface treatments, their example constituency and function are generally as described above. As such, the curved surface 202 can also be referred to as a dichroic curved surface 202.

The transparent material defining the curved surface 202 also defines a transverse support rib 206. The transverse support rib 206 (depicted end-on) is analogous to the support rib 108 (or 110) as described above. The material defining the curved surface 202 further defines a side support rib 208. Both the transverse support rib 206 and the side support rib 208 are defined by a thickness “T2” extending away from a backside 210 of the curved surface 202. In one example, the thickness T2 is about 1.5 millimeters. Other suitable thicknesses can also be used. In one example, the backside 210 of the curved surface 202 includes an anti-reflective surface treatment.

The device 200 includes a curved surface 212. The curved surface 212 is defined by a parabolic, parabolic segment, or other suitable curvature. The curved surface 212 is formed from plastic, glass, metal or another suitable material. The curved surface 212 includes a reflective surface treatment 214 borne or formed thereon. In one example, the reflective surface treatment is a thin-film deposition of aluminum overlaid with a protective layer of transparent silicon dioxide (SiO₂). Other suitable reflective materials or protective layers can also be used. As such, the curved surface 212 can also be referred to as a reflective curved surface 212.

The curved surface 212 is defined by a surface curvature consistent with that of the curved surface 202. That is, the curved surface 212 is defined by a parabola, segment of a parabola, and so on, in accordance with the surface geometry of the curved surface 202. The curved surface 212 is in spaced adjacency with the curved surface 202, having the reflective surface treatment 214 facing toward the backside 210. In one example, the spacing “S1” between the curved surface 202 and the curved surface 212 is about 11.0 millimeters. Other suitable spacing (i.e., offsets) can also be used. The pacing S1 is essentially constant everywhere between the respective curved surfaces 202 and 212 due to the corresponding surface curvatures of each.

The portion of the device 200 includes elements and their relative orientation as contemplated by various examples of the present teachings. In one example, the concentrator 100 defines a portion of the device 200. The respective functions of the dichroic curved surface 202 and the reflective curved surface 212 are generally as described below with respect to the example of FIG. 3.

### Illustrative Optical Arrangement

Reference is now made to FIG. 3, which depicts a schematic view of an optical arrangement 300 in accordance with another example of the present teachings. The arrangement 300 is illustrative and non-limiting with respect to the present teachings. Other systems, devices, arrangements and so on are contemplated.

The arrangement 300 includes a curved transparent surface 302 bearing a dichroic surface treatment thereon, and is also referred to as a dichroic surface 302. The dichroic surface 302 has a parabolic curvature in at least one axis. In one example, the dichroic surface 302 is analogous to the light concentrator 100. Other examples and form factors are also contemplated.

The arrangement 300 also includes a curved surface 304 bearing a reflective surface treatment thereon, and is also referred to as a reflective surface 304. The reflective surface 304 also has a parabolic curvature in at least one axis, in accordance with the curvature of the dichroic surface 302. In one example, the reflective surface 302 is essentially equivalent to the reflective curved surface 212. The reflective surface 304 is spaced apart from the dichroic surface 302.

Typical operation of the arrangement 300 is as follows: photonic energy, such as sunlight, is incident upon the dichroic surface 302. Such incident photonic energy is represented by a single ray 306 in the interest of clarity. However, it is to be understood that during normal operation, such photonic energy (e.g., sunlight) would be incident upon the entire surface area (or nearly so) of the dichroic surface 302.

A first spectral portion (or band) 308 of the incident photonic energy 306 is reflected away from the dichroic surface 302 and is concentrated upon a first target 310. In one example, the first spectral portion 308 is defined by photonic energies in the range of about four-hundred nanometers to about eight-hundred and fifty nanometers in wavelength. Other suitable spectral portions can also be defined in accordance with the particular dichroic surface treatment borne by the curved surface 302.

A second spectral portion 312 of the incident photonic energy 306 passes through the dichroic surface 302 and is incident upon the reflective surface 304. The second spectral portion 312 is then is reflected away from the reflective surface 304 and is concentrated upon a second target 314. In one example, the second spectral portion 312 is defined by photonic energies in the range of about eight-hundred and fifty nanometers to about twelve-hundred nanometers in wavelength. Other suitable spectral portions can also be defined in accordance with the particular dichroic surface treatment borne by the curved surface 302.

In one example, the first and second targets 310 and 314 are defined by respective photovoltaic (PV) cells each configured to generate electrical energy by way of direct conversion of photonic energy. Targets 310 or 314 configured for absorption of thermal (infrared) energy can also be used. Other suitable definitions or combinations of first and second targets 310 and 314 can also be used. The energies (i.e., electrical, thermal, and so on) generated by the targets 310 and 314 can be coupled to a suitable load or loads, or used in other ways.

The respective targets 310 and 314 can be defined or selected in accordance with the particular spectral band of photonic energy concentrated thereon. Thus, the targets 310 and 314 can be optimized for use with the dichroic surface 302 and the reflective surface 304. It is also noted that the respective first and second targets 310 and 314 are spaced apart from each other in accordance with the distinct photonic energy concentration regions defined by the dichroic surface 302 and the reflective surface 304.

### Illustrative Light Concentrating Device

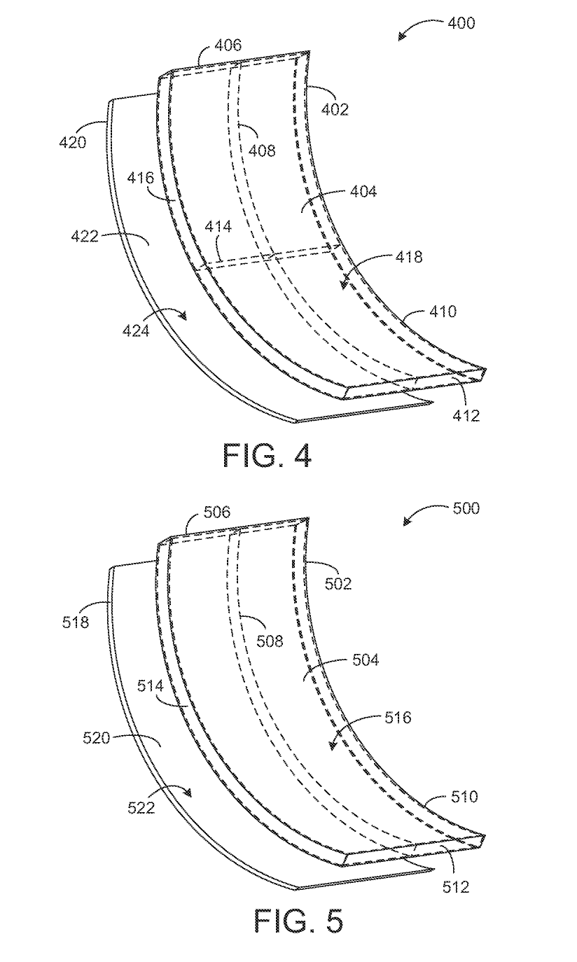

Reference is made now to FIG. 4, which depicts an isometric-like view of a light concentrating device (device) 400 in accordance with another example of the present teachings. The device 400 is illustrative and non-limiting with respect to the present teachings. Other devices, systems and apparatus can also be defined and used according to the present teachings.

The device 400 includes a light concentrator 402. The light concentrator 402 includes a curved surface 404 having a parabolic (or segment of a parabola) cross-sectional shape in one axis. The light concentrator 402 also includes respective support ribs 406, 408, 410, 412, 414 and 416, inclusive. The support ribs 406-416 function to stiffen the light concentrator 402 and maintain the desired curvature of the curved surface 404. The light concentrator 402 is formed from any suitable transparent material such as plastic, glass, and so on. Other materials can also be used. In one example, the light concentrator 402 is formed of plastic by injection molding.

The device 400 includes a dichroic surface treatment 418 borne by or formed upon the curved surface 404. The dichroic surface treatment 418 can be formed (or deposited) as one or more layers of one or more dichroic materials. Non-limiting examples of such dichroic materials include those described above. Other suitable materials can also be used.

The dichroic surface treatment 418 functions to reflect a first spectral band of incident photonic energy (e.g., sunlight) away from the light concentrator 402. The reflected first spectral band is concentrated onto a strip-like target region by virtue of the parabolic curvature of the curved surface 404. The dichroic surface treatment 418 further functions to allow a second spectral band of incident photonic energy to pass there through and through the transparent material of the light concentrator 402. In one example, the second spectral band is of longer wavelengths than the first spectral band. Other configurations can also be used.

The device 400 also includes a light concentrator 420. The light concentrator 420 includes a curved surface 422 having a parabolic (or segment of a parabola) cross-sectional shape in one axis. The light concentrator 420 can be formed from plastic, glass, metal, and so on. Other materials can also be used. The light concentrator 420 need not be formed from a transparent material, but can optionally be so. The light concentrator 420 is spaced apart from and shifted relative to the concentrator 402 and faces toward a backside thereof. The light concentrator 420 receives the second spectral band of photonic energy that passes through the light concentrator 402.

The light concentrator 420 includes a reflective surface treatment 424 borne or formed thereon. In one example, the reflective surface treatment 424 is defined by an aluminum film over-coated with a protective layer of transparent silicon dioxide (SiO₂). Other reflective surface treatments can also be used. The reflective surface treatment 424 functions to reflect the second spectral band of photonic energy away from the light concentrator 420, while the curved surface 422 functions to concentrate that photonic energy onto a strip-like target region.

The light concentrator 402 and the light concentrator 420 operate mutually and respectively so as to concentrate two distinct spectral bands or ranges of photonic energy (i.e., sunlight) onto two distinct target regions. This general operation is analogous to that described above in regard to the optical arrangement 300. Incident photonic energy, such as solar radiation, is therefore divided or split into two spectral bands and concentrated onto respective targets that can be optimized for such exposure.

In turn, the curved surface 404 and the respective support ribs 406-416 of the light concentrator 402 are portions of a monolithic structure (or entity) that is formed by injection molding or another suitable process. It is noted that the light concentrator 402 includes six respective support ribs 406-416, in contrast to the seven respective support ribs 104-116 of the light concentrator 100. The present teachings contemplate various examples of light concentrator formed from transparent materials and having various dimensions, aspect ratios, surface curvatures, support rib configurations, and so on.

### Another Illustrative Light Concentrating Device

Reference is made now to FIG. 5, which depicts an isometric-like view of a light concentrating device (device) 500 in accordance with another example of the present teachings. The device 500 is illustrative and non-limiting with respect to the present teachings. Other devices, systems and apparatus can also be defined and used according to the present teachings.

The device 500 includes a light concentrator 502. The light concentrator 502 includes a curved surface 504 having a parabolic or parabolic segment cross-sectional shape in one axis. The light concentrator 502 also includes respective support ribs 506, 508, 510, 512 and 514, inclusive. The support ribs 506-514 function to stiffen the light concentrator 502 and maintain the desired curvature of the curved surface 504. The light concentrator 502 is formed from a suitable transparent material such as plastic, glass, and so on. Other materials can also be used. In one example, the light concentrator 502 is formed of plastic by injection molding.

The device 500 includes a dichroic surface treatment 516 borne by or formed upon the curved surface 504. The dichroic surface treatment 516 can be formed (or deposited) as one or more layers of one or more dichroic materials. Non-limiting examples of such dichroic materials include those described above. Other suitable materials can also be used.

The dichroic surface treatment 516 functions to reflect a first spectral band of incident photonic energy (e.g., sunlight) away from the light concentrator 502. The reflected first spectral band is concentrated in a strip-like target region by the parabolic curvature of the curved surface 504. A second spectral band of incident photonic energy passes through the dichroic surface treatment 516 and the transparent material of the light concentrator 502.

The device 500 also includes a light concentrator 518. The light concentrator 518 includes a curved surface 520 having a parabolic (or segment of a parabola) cross-sectional shape in one axis. The light concentrator 518 can be formed from plastic, glass, metal, and so on. Other materials can also be used. The light concentrator 518 is spaced apart from the concentrator 502 and faces toward a backside thereof. The light concentrator 518 receives the second spectral band of photonic energy that passes through the light concentrator 502.

The light concentrator 518 includes a reflective surface treatment 522 borne or formed thereon. In one example, the reflective surface treatment 522 is defined by a deposition of aluminum protected by a layer of transparent silicon dioxide (SiO₂). Other reflective surface treatments can also be used. The reflective surface treatment 522 functions to reflect the second spectral band of photonic energy away from the light concentrator 518, while the curved surface 520 functions to concentrate that photonic energy onto a strip-like target region.

The light concentrator 518 and the light concentrator 502 operate to concentrate two distinct spectral bands of photonic energy onto two distinct target regions. This general operation is essentially as described above in regard to the optical arrangement 300. Incident photonic energy, such as solar radiation, is therefore divided or split into two spectral bands and concentrated onto respective targets that can be optimized for operation under such exposure.

It is noted that the light concentrator 502 includes five respective support ribs 506-514, in contrast to those respective support rib counts of the light concentrators 100 and 400 as described above. Again, the present teachings contemplate various examples of light concentrators having various support rib configurations, and so on.

### Illustrative Solar Energy System

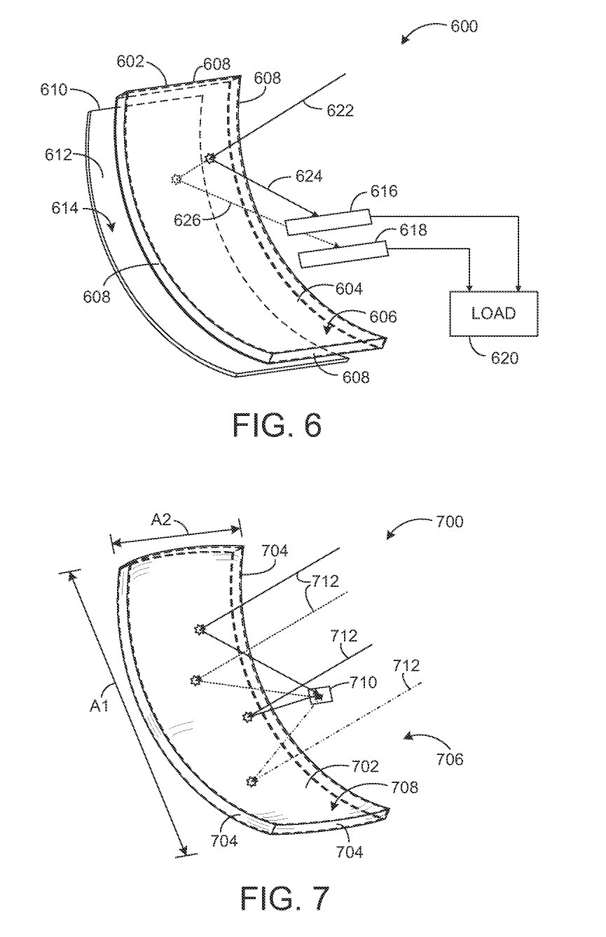

Attention is now turned to FIG. 6, which depicts a hybrid view of solar energy system (system) 600 according to another example of the present teachings. The system 600 is illustrative and non-limiting with respect to the present teachings. Other systems, devices and apparatus can also be used.

The system 600 includes a first light concentrator 602. The first light concentrator 602 is defined by a transparent, monolithic entity having a curved surface 604 bearing a dichroic surface treatment 606. The first light concentrator 602 can be formed by injection molding of plastic, and so on, and includes respective support ribs 608 defined about the periphery thereof. Thus, the first light concentrator 602 generally defines a box-like structural form.

The system 600 includes a second light concentrator 610 having a curved surface 612 and bearing a reflective surface treatment 614. The second light concentrator 610 is supported behind and spaced apart from the first light concentrator 602.

The system 600 also includes a first photovoltaic cell 616 configured to generate electrical energy by direct conversion of incident photonic energy. The first photovoltaic cell is supported at a first target region as defined by the first light concentrator 602. The first photovoltaic cell 616 is defined by operating characteristics consistent with a first spectral band of photonic energy concentrated thereon. Thus, the first photovoltaic cell 616 is optimized (or nearly so) in accordance with the first light concentrator 602.

The system 600 also includes a second photovoltaic cell 618 configured to generate electrical energy by direct conversion. The first photovoltaic cell is supported at a second target region defined by the second light concentrator 610. The first photovoltaic cell 618 is defined by operating characteristics consistent with a second spectral band of photonic energy concentrated thereon by the first light concentrator 610. Thus, the first photovoltaic cell 618 is optimized (or nearly so) for use with the second light concentrator 610. It is noted that the first and second photovoltaic cells 616 and 618 are spaced apart from each other in accordance with the first and second target regions, respectively.

The system 600 also includes an electrical load 620. The electrical load 620 is coupled to receive electrical energy from the first and second photovoltaic cells 616 and 618, respectively. The electrical load 620 can be defined by any suitable electrical or electronic device. Non-limiting examples of such an electrical load 620 include electronic circuitry, a storage battery, power conditioning circuitry, cellular communications equipment, a global positioning satellite (OPS) receiver, a computer, and so on. Other electrical loads 620 can also be used.

Normal, typical operations of the system 600 are as follows: photonic radiation, such as sunlight, is incident upon the first light concentrator 602. A single ray 622 is depicted in the interest of clarity. However, it is to be understood that the entire curved surface 604 is exposed to photonic radiation during normal operations.

The ray 622 strikes the dichroic surface treatment 606 and a first spectral portion 624 is reflected away there from. The parabolic curvature of the curved surface 604 causes the reflected first spectral portion 624 to be concentrated onto the first photovoltaic cell 616 in a bar or strip-like pattern. A second spectral portion 626 of the ray 622 passes through the dichroic surface treatment 606 and the transparent material of the first light concentrator 602 and strikes the second light concentrator 610.

The second spectral portion 626 is reflected away by the reflective surface treatment 614 and is concentrated upon the second photovoltaic cell 618 by virtue of the curved surface 612. The photovoltaic cells 616 and 618 generate electrical energy by direct conversion of the first and second spectral bands 624 and 626, respectively. The electrical energy is coupled to the electrical load 620 for use in accordance with the particular function or functions thereof.

### Illustrative Double-Curvature Concentrator

Reference is now made to FIG. 7, which depicts an isometric-like view of a double-curvature light concentrator (concentrator) 700 according to another example of the present teachings. The concentrator 700 is illustrative and non-limiting with respect to the present teachings. Other light concentrators, devices and systems can also be defined and used.

The concentrator 700 includes a surface 702 defined by a parabolic curvature in a first, longitudinal axis “A1”, and a parabolic curvature in a second, transverse axis “A2”. The surface 702 is also referred to as a double-curvature surface 702 as a result. The concentrator 700 also includes respective support ribs 704 about the periphery of the surface 702 and extending away from a backside thereof. The surface 702 and the support ribs 704 are respective portions of a monolithic entity 706 formed by way of injection molding or another suitable process. The entity 706 can be formed from any suitable transparent material (i.e., plastic, and so on).

The concentrator 700 also includes a dichroic surface treatment 708 borne by or formed upon the surface 702. The dichroic surface treatment 708 can be defined as described above and is configured to reflect a first spectral band of incident photonic energies, while permitting a second spectral band of the incident photonic energies to pass there through.

The concentrator 700 is configured to concentrate the first spectral band of incident photonic energies 712 upon a spot-like target region 710. The double-curvature surface 702 functions to cause the spot-like (as opposed to strip- or bar-like) energy concentration pattern on the target 710. The present teachings therefore contemplate light concentrating devices having various surface curvatures. The concentrator 700 can be used in combination with a reflective curved surface having double-curvature so as to define a spectral band splitting and concentrating system analogous to those described above.

### Illustrative Method

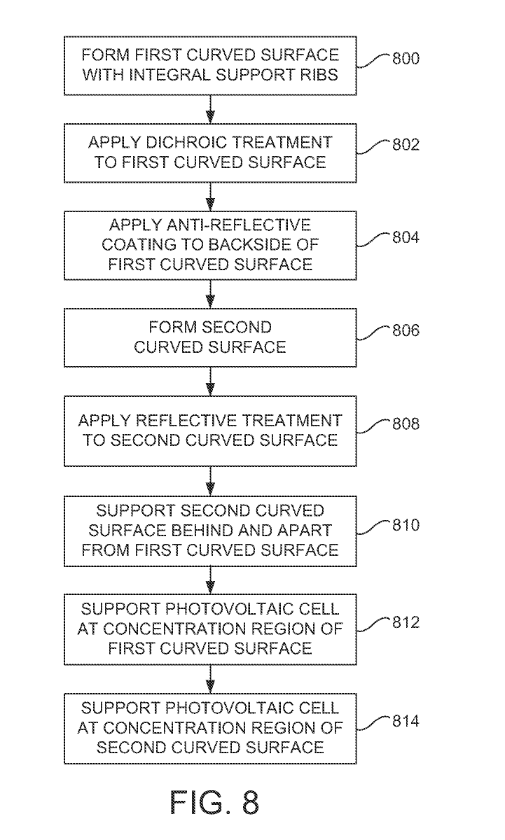

Reference is now made to FIG. 8, which depicts a flow diagram of a method according to the present teachings. The method of FIG. 8 includes particular operations and order of execution. However, other methods including other operations, omitting one or more of the depicted operations, and/or proceeding in other orders of execution can also be used according to the present teachings. Thus, the method of FIG. 8 is illustrative and non-limiting in nature. Reference is made to FIGS. 1 and 6 in the interest of understanding FIG. 8.

At 800, a first curved surface is formed with integral support ribs. For purposes of illustration, it is assumes that a transparent light concentrator 602 is formed by injection molding. The light concentrator 602 includes a curved surface 604 and a plurality of stiffening support ribs 608 about the periphery of the curved surface 604. The support ribs 608 and the curved surface 604 are portions of a monolithic construct.

At 802, a dichroic surface treatment is applied to the first curved surface. For purposes of the present illustration, a dichroic surface treatment 606 is applied to the curved surface 604. The dichroic surface treatment 606 can be defined by any suitable number of distinct dichroic materials arranged as any number of respective layers. The dichroic surface treatment 606 thus defines a photonic band-pass filter, reflecting a first spectral band of photonic (light) energies, and passing a second spectral band there through.

At 804, an anti-reflective coating is applied to the backside of the first curved surface. For purposes of the present illustration, an anti-reflective coating is applied to a backside of the curved surface 604—see the anti-reflective coating 122 of the backside of curved surface 102 for an analogous depiction.

At 806, a second curved surface is formed. For purposes of the present illustration, a second light concentrator 610 is formed by injection molding of plastic. The light concentrator 610 is defined by a curved surface 612 that is parabolic in cross-sectional form.

At 808, a reflective treatment is applied to the second curved surface. For purposes of the present illustration, a reflective coating 614 is applied to the curved surface 612. The reflective coating (or surface treatment) 614 is defined by a deposition of reflective aluminum metal over-coated by a protective layer of silicon dioxide.

At 810, the second curved surface is supported behind and apart from the first curved surface. In the present illustration, the curved surface 612 is supported behind the curved surface 604, with the respective surfaces 612 and 604 being separated by a generally uniform distance of about 11.0 millimeters.

At 812, a photovoltaic cell is supported at the concentration region defined by the first curved surface. For purposes of the present illustration, a photovoltaic cell 616 is supported at a photonic energy concentration target region defined by the curved surface 604. The dichroic coating 606 and the curvature of the surface 604 are such that a first spectral band 624 of incident photonic energy is concentrated onto the photovoltaic cell 616 during normal use.

At 814, a photovoltaic cell is supported at the concentration region defined by the second curved surface. For purposes of the present illustration, a photovoltaic cell 618 is supported at a photonic energy concentration target region defined by the curved surface 612. The reflective coating 614 and the curvature of the surface 612 are such that a second spectral band 626 of incident photonic energy is concentrated onto the photovoltaic cell 618 during normal use.

In general, and without limitation, the present teachings contemplate light concentrators and solar energy systems using such concentrators. A first light concentrator is formed by injection molding of plastic or another suitable material. The resulting monolithic structure is transparent in nature and is defined by a curved surface and a plurality of support ribs that stiffen and maintain the surface curvature. The curved surface is parabolic or a segment of a parabola in one or more axis.

A dichroic surface treatment is applied to or borne upon the curved surface of the first light concentrator. The dichroic surface treatment can include any number of suitable materials in any suitable arrangement (order of layers, respective thicknesses, and so on). The dichroic surface treatment is such that a first spectral band of incident photonic energies, such as sunlight, is reflected away from the curved surface and concentrated onto a first target region. A second spectral band of the incident photonic energies is passed through the dichroic surface treatment and the transparent structure of the first light concentrator.

A second light concentrator is formed by injection molding of plastic, formed from sheet metal, or another suitable material. The resulting structure is defined by a curved surface that is parabolic or a segment of a parabola in one or more axis.

A reflective surface treatment is applied to or borne upon the curved surface of the second light concentrator. The reflective surface treatment can include any number of suitable materials in any suitable arrangement. The reflective surface treatment is such that the second spectral band of incident photonic energy, as received through the first light concentrator, is reflected away from the curved surface and concentrated onto a second target region

Respective photovoltaic cells, or other suitable entities, can be disposed at the first and second target regions so that the first and second spectral bands, respectively, are concentrated thereon. The photovoltaic cells or other target entities can be selected (optimized) in accordance with the spectral concentration characteristics of the first and second light concentrators.

The curved surfaces of the light concentrators are defined by relatively thin material dimensions, while surface contour errors are eliminated or minimized by virtue of the stiffening support ribs. Rapid and economical mass production of light energy concentrators and corresponding solar energy systems are contemplated by the present teachings.

In general, the foregoing description is intended to be illustrative and not restrictive. Many embodiments and applications other than the examples provided would be apparent to those of ordinary skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future embodiments. In sum, it should be understood that the invention is capable of modification and variation and is limited only by the following claims.

What is claimed is:

1. An apparatus, comprising:
a first surface and support ribs extending away from a backside of the first surface such that a monolithic structure is defined;
a dichroic surface treatment borne on the first surface to concentrate a first spectral band of incident photonic energies onto a first target region;
a second surface spaced apart from the backside of the first surface; and
a reflective surface treatment borne on the second surface to concentrate a second spectral band of photonic energies onto a second target region.

2. The apparatus of claim 1, the dichroic surface treatment such that the second spectral band passes through the first surface and is incident upon the second surface.

3. The apparatus according to claim 1 the dichroic surface treatment including at least niobium pentoxide (Nb₂O₅), silicon dioxide (SiO₂), titanium dioxide (TiO2), tantalum pentoxide (Ta2O5), zirconium pentoxide (Zr2O5), hafnium dioxide (HfO2), magnesium fluoride (MgF2) or aluminum oxide (Al2O3).

4. The apparatus according to claim 1, the first surface and the support ribs being formed by injection molding.

5. The apparatus according to claim 1, at least some of the support ribs disposed about the periphery of the first surface such that a box-like structure is defined.

6. The apparatus according to claim 1 further comprising a photovoltaic cell disposed at the first target region, the first spectral band of photonic energies corresponding to characteristics of the photovoltaic cell.

7. The apparatus according to claim 1 further comprising an anti-reflective surface treatment borne on the backside of the first surface.

8. A solar energy device, comprising:
a first photovoltaic cell and a second photovoltaic cell each configured to convert photonic energy into electrical energy;
a transparent material formed to define a first parabolic surface and stiffening support ribs extending away there from, the first parabolic surface bearing a dichroic surface treatment to concentrate a first spectral band of photonic energies onto the first photovoltaic cell; and
a material formed to define a second parabolic surface spaced apart from a backside of the first parabolic surface, the second parabolic surface bearing a reflective surface treatment to concentrate a second spectral band of photonic energies onto the second photovoltaic cell.

9. The solar energy device according to claim 8, the transparent material being injection molded so as to form the first parabolic surface and the stiffening support ribs as portions of a monolithic structure.

10. The solar energy device according to claim 8, the first parabolic surface defined by a single curvature so as to concentrate the first spectral band of photonic energies as a strip-like area onto the first photovoltaic cell.

11. The solar energy device according to claim 8, the first parabolic surface defined by a double curvature so as to concentrate the first spectral band of photonic energies as a spot-like area onto the first photovoltaic cell.

12. The solar energy device according to claim 8, the material being injection molded so as to form the second parabolic surface.

13. A method, comprising:
forming a transparent material to define a first surface having a parabolic curvature in at least one axis, the transparent material also formed to define stiffening support ribs extending away from a backside of the first surface;
applying a dichroic surface treatment to the first surface to concentrate a first spectral portion of incident light energy onto a first target region;
forming a material to define a second surface having a parabolic curvature in at least one axis; and
applying a reflective surface treatment to the second surface to concentrate a second spectral portion of the incident light energy onto a second target region distinct from the first target region.

14. The method according to claim 13, the forming the transparent material including injection molding.

15. The method according to claim 13 further comprising disposing the second surface in spaced adjacency to the backside of the first surface.
